(19) United States
(12) Patent Application Publication
(10) Pub. No.: US 2007/0262312 A1
(43) Pub. Date: Nov. 15, 2007

(54) THIN FILM TRANSISTOR ARRAY SUBSTRATE STRUCTURES AND FABRICATION METHOD THEREOF

(75) Inventors: Yu-Wei Liu, Taipei County (TW); Feng-Yuan Gan, Hsinchu City (TW); Shu-Chin Lee, Taichung County (TW); Yen-Heng Huang, Taipei County (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU OPTRONICS CORP., Hsinchu (TW)

(21) Appl. No.: 11/461,015

(22) Filed: Jul. 31, 2006

(30) Foreign Application Priority Data
May 11, 2006 (TW) 95116687

(51) Int. Cl. H01L 29/786; H01L 21/00

(52) U.S. Cl. 257/72; 438/609; 438/73; 438/70; 257/443

(57) ABSTRACT

A thin film transistor array substrate structure. The array substrate structure includes a thin film transistor array substrate, an organic material layer formed thereon, and a plurality of black matrices and color filter patterns disposed on the organic material layer. The invention also provides a method of fabricating the thin film transistor array substrate.

### BACKGROUND OF THE INVENTION

1. Field of the Invention

The invention relates to a semiconductor structure, and in particular to a thin film transistor array substrate structure and fabrication method thereof.

2. Description of the Related Art

Liquid crystal displays (LCDs) are popularly utilized in personal computers, word processors, navigation systems, amusement machines, projectors, viewfinders and portable machines (such as watches, electronic calculators and televisions) because of low power consumption, thin profile, light weight and low driving voltage.

A color filter (CF) is a key component of a color LCD. Typically, the color filter and thin film transistors (TFTs), which act as driving switches, are disposed on two separate substrates and located on the opposite side of the liquid crystal layer. To prevent light from damaging the TFTs, a black matrix is formed on the color filter's substrate, above the thin film transistors. This arrangement, however, increases costs, processing time, and manufacturing complexity. Additionally, the black matrix must be wider in consideration of alignment errors, thus reducing panel aperture ratio.

In order to increase the panel aperture ratio, a color filter on array (COA) technique has been developed. The conventional COA method, however, requires 9 processes including 5 array processes and 4 color filter processes, increasing costs.

### BRIEF SUMMARY OF THE INVENTION

The invention provides a thin film transistor array substrate structure comprising a thin film transistor array substrate, an organic material layer formed thereon, and a plurality of black matrices and color filter patterns disposed on the organic material layer.

The invention also provides a method of fabricating a thin film transistor array substrate structure comprising providing a thin film transistor array substrate, coating an organic material layer thereon, forming a plurality of black matrices on the organic material layer, printing a plurality of color filter patterns onto the organic material layer by ink-jet printing, forming an opening through the black matrix and portions of the organic material layer by laser ablation to expose the thin film transistor, and forming a transparent conductive layer on the black matrices, color filter patterns and opening surface to electrically connect to the thin film transistor.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawing, wherein:

FIG. 1 is a cross section of a thin film transistor array substrate structure of the invention.

FIGS. 2A˜2F are cross sections of a fabrication method of a thin film transistor array substrate structure of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The invention provides a thin film transistor array substrate structure comprising a thin film transistor array substrate, an organic material layer formed thereon, and a plurality of black matrices and color filter patterns disposed on the organic material layer.

The organic material layer may comprise benzocyclobutane (BCB), acrylic or methylsilazane (MSZ). The black matrix may comprise organic materials and has a thickness less than 5 μm. The color filter patterns may comprise organic dyes or pigments.

The array substrate structure further comprises an opening through the black matrix and portions of the organic material layer and a transparent conductive layer such as an indium tin oxide layer formed on the black matrices, color filter patterns and opening surface, electrically connecting to the thin film transistor.

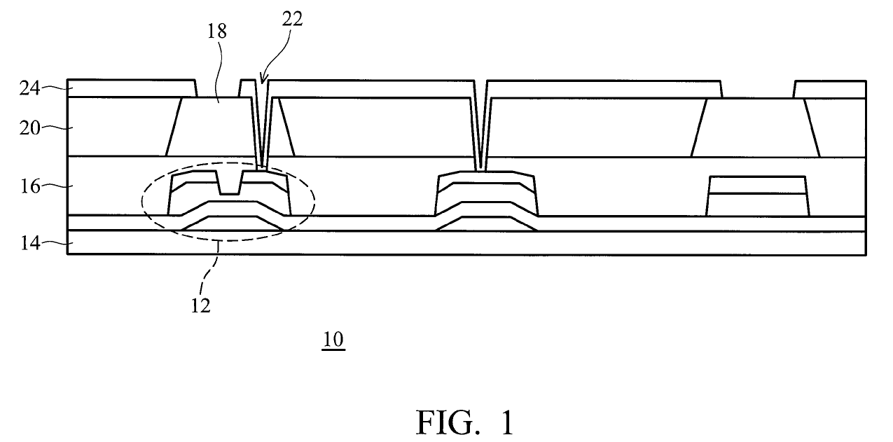

A thin film transistor array substrate structure 10 of the invention, as shown in FIG. 1 comprises a thin film transistor 12 disposed on a substrate 14, an organic material layer 16, and a plurality of black matrices 18 and color filter patterns 20. The organic material layer 16 is formed on the substrate 14 and thin film transistor 12. The black matrices 18 and color filter patterns 20 are disposed on the organic material layer 16. The substrate structure 10 further comprises an opening 22 through the black matrix 18 and portions of the organic material layer 16 and an indium tin oxide layer 24 formed on the black matrices 18, color filter patterns 20 and opening surface, electrical connecting to the thin film transistor 12.

The invention also provides a method of fabricating a thin film transistor array substrate structure, comprising the following steps. A thin film transistor array substrate is provided. Next, an organic material layer is coated on the substrate. A plurality of black matrices are then formed on the organic material layer. Next, a plurality of color filter patterns are printed onto the organic material layer by ink-jet printing. An opening is then formed through the black matrix and portions of the organic material layer by laser ablation to expose the thin film transistor. Finally, a transparent conductive layer is formed on the black matrices, color filter patterns and opening surface to electrically connect to the thin film transistor.

The organic material layer may comprise benzocyclobutane (BCB), acrylic or methylsilazane (MSZ). The black matrix may comprise organic materials and the color filter patterns may comprise organic dyes or pigments.

The black matrices are formed on the organic material layer by lithography or laser ablation. The laser ablation has a laser energy density of about 10 J/cm²˜0.25 mJ/cm². The color filter patterns are printed onto the organic material layer at a printing rate of about 10 pl/drop˜5 μl/drop. Additionally, the transparent conductive layer such as indium tin oxide layer is formed on the black matrices, color filter patterns and opening surface by sputtering or coating.

Conventional silicon nitride or silicon oxynitride serves as a source/drain insulating protective layer. However, when an electrical connecting opening is formed through such material, a series of processes such as chemical vapor deposition, resist coating, exposure, development, etching, and resist stripping are required, resulting in complicated processes and high cost. In the invention, the novel organic material is substituted for the original material and planarization is achieved.

The processes of the thin film transistor array substrate structure include a combination of an ink-jet printing for fabricating color filter patterns (RGB colors) and a laser ablation for forming an electrical connecting opening. Compared to conventional lithography, this color filter on array (COA) process is simplified, significantly reducing cost.

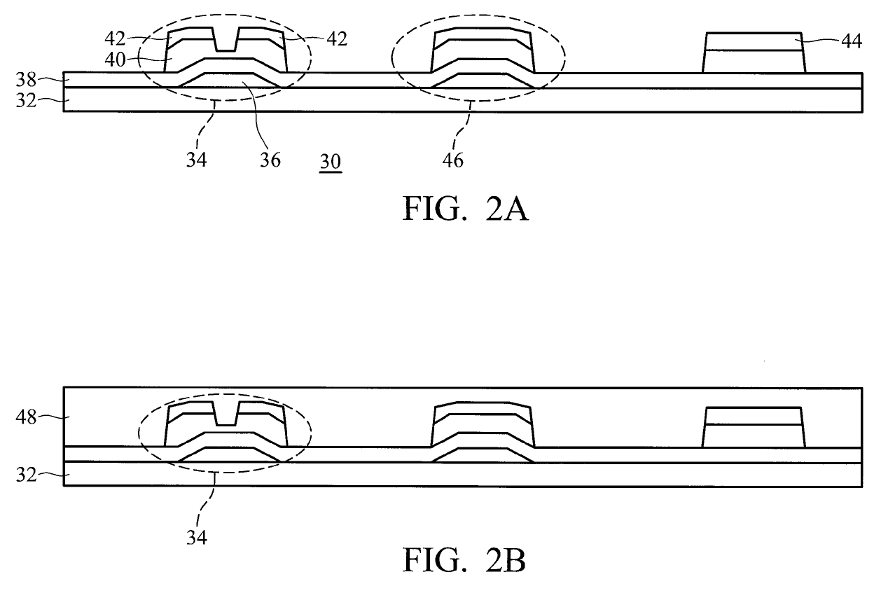

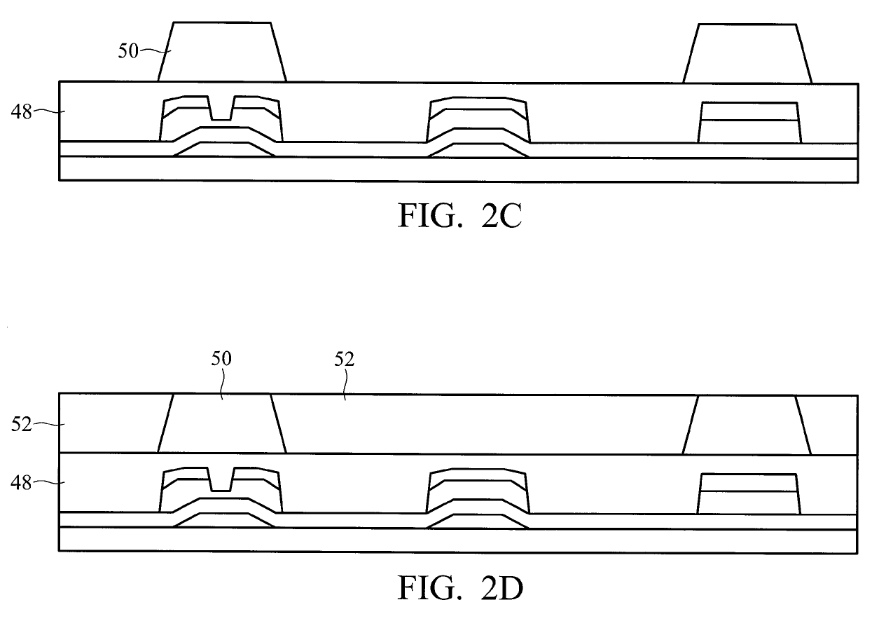

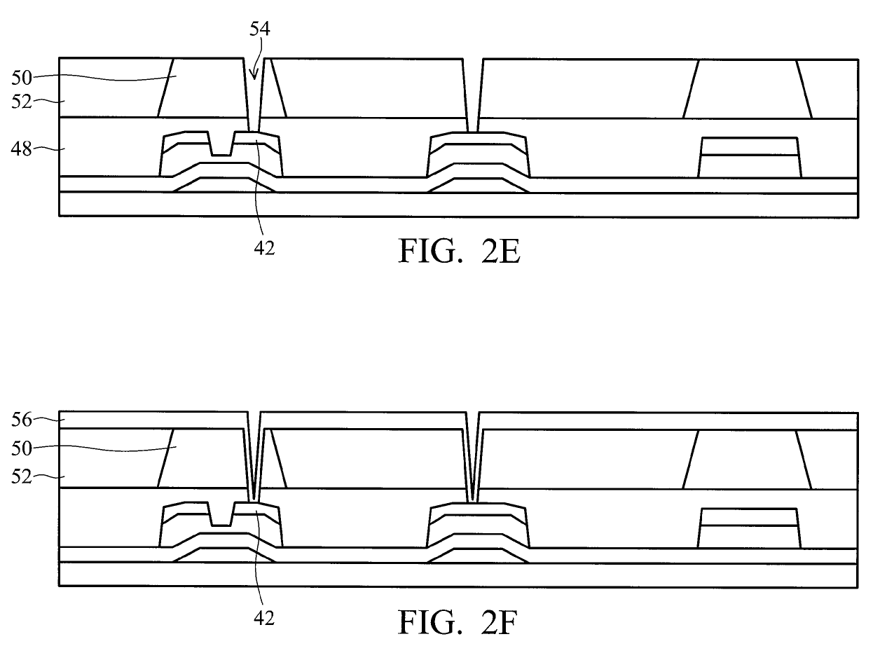

The fabrication method of the thin film transistor array substrate structure of the invention is disclosed in FIGS. 2A˜2F.

Referring to FIG. 2A, a thin film transistor array substrate 30 comprising a substrate 32 such as glass substrate and a thin film transistor 34 disposed thereon is provided. The thin film transistor 34 is composed of a gate electrode 36, an insulating layer 38 such as silicon dioxide, an amorphous silicon/n⁺ amorphous silicon layer 40, and source/drain 42 formed by a metal layer. A metal data line 44 connected to the source is further formed on a specific area of the substrate 32. Generally, the gate electrode 36 is arranged in a horizontal orientation and the data line 44 in a vertical orientation, thereby defining a plurality of rectangular pixels (not shown). Also, a storage capacitor 46 connected to the drain is fabricated on the substrate 32.

Referring to FIG. 2B, an organic material layer 48 is coated on the substrate 32 and the thin film transistor 34. The organic material layer may comprise benzocyclobutane (BCB), acrylic or methylsilazane (MSZ).

Next, a plurality of black matrices 50 are defined on the organic material layer 48 by lithography or laser ablation, as shown in FIG. 2C. The black matrix 50 may comprise organic materials. The laser ablation has a laser energy density of about 10 J/cm²˜0.25 mJ/cm².

Referring to FIG. 2D, a plurality of color filter patterns 52 such as RGB colors are printed onto the organic material layer 48 by ink-jet printing. The color filter patterns 52 may comprise organic dyes and are printed at a printing rate of about 10 pl/drop˜5 μl/drop.

Referring to FIG. 2E, an opening 54 is formed through the black matrix 50 and portions of the organic material layer 48 to expose the source/drain 42 of the thin film transistor 34 by laser ablation having a laser energy density of about 10 J/cm²˜0.25 mJ/cm².

Referring to FIG. 2F, an indium tin oxide layer 56 is formed on the black matrices 50, color filter patterns 52 and the surface of the opening 54 to electrically connect to the source/drain 42 of the thin film transistor 34.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A thin film transistor array substrate structure, comprising:
a thin film transistor array substrate;
an organic material layer formed thereon; and
a plurality of black matrices and color filter patterns disposed on the organic material layer.

2. The thin film transistor array substrate structure as claimed in claim 1, wherein the organic material layer comprises benzocyclobutane (BCB), acrylic or methylsilazane (MSZ).

3. The thin film transistor array substrate structure as claimed in claim 1, wherein the black matrix comprises organic materials.

4. The thin film transistor array substrate structure as claimed in claim 1, wherein the black matrix has a thickness less than 5 μm.

5. The thin film transistor array substrate structure as claimed in claim 1, wherein the color filter pattern comprises organic dyes or pigments.

6. The thin film transistor array substrate structure as claimed in claim 1, further comprising an opening through the black matrix and portions of the organic material layer, connecting to the thin film transistor.

7. The thin film transistor array substrate structure as claimed in claim 6, further comprising a transparent conductive layer formed on the black matrices, color filter patterns and opening surface, electrical connecting to the thin film transistor.

8. The thin film transistor array substrate structure as claimed in claim 7, wherein the transparent conductive layer comprises an indium tin oxide layer.

9. A method of fabricating a thin film transistor array substrate structure, comprising:
providing a thin film transistor array substrate;
coating an organic material layer thereon;
forming a plurality of black matrices on the organic material layer;
printing a plurality of color filter patterns onto the organic material layer by ink-jet printing;
forming an opening through the black matrix and portions of the organic material layer by laser ablation, exposing the thin film transistor; and
forming a transparent conductive layer on the black matrices, color filter patterns and opening surface, electrically connecting to the thin film transistor.

10. The method of fabricating a thin film transistor array substrate structure as claimed in claim 9, wherein the organic material layer comprises benzocyclobutane (BCB), acrylic or methylsilazane (MSZ).

11. The method of fabricating a thin film transistor array substrate structure as claimed in claim 9, wherein the black matrices are formed on the organic material layer by lithography or laser ablation.

12. The method of fabricating a thin film transistor array substrate structure as claimed in claim 11, wherein the laser ablation has a laser energy density of about 10 J/cm²˜0.25 mJ/cm².

13. The method of fabricating a thin film transistor array substrate structure as claimed in claim 9, wherein the black matrix comprises organic materials.

14. The method of fabricating a thin film transistor array substrate structure as claimed in claim 9, wherein the ink-jet printing has a printing rate of about 10 pl/drop˜5 μl/drop.

15. The method of fabricating a thin film transistor array substrate structure as claimed in claim 9, wherein the color filter pattern comprises organic dyes or pigments.

16. The method of fabricating a thin film transistor array substrate structure as claimed in claim 9, wherein the transparent conductive layer comprises an indium tin oxide layer.

17. The method of fabricating a thin film transistor array substrate structure as claimed in claim 9, wherein the indium tin oxide layer is formed on the black matrices, color filter patterns and opening surface by sputtering or coating.
